(19) United States
(12) Patent Application Publication
(10) Pub. No.: US 2008/0073649 A1
(43) Pub. Date: Mar. 27, 2008

(54) THIN FILM TRANSISTOR SUBSTRATE AND MANUFACTURING METHOD THEREOF

(76) Inventors: Young Il Kim, Suwon-si (KR); Chun Gi You, Hwaseong-si (KR); Bong Ju Kim, Suwon-si (KR)

Correspondence Address: F. CHAU & ASSOCIATES, LLC, 130 WOODBURY ROAD, WOODBURY, NY, 11797, US

(21) Appl. No.: 11/860,038

(22) Filed: Sep. 24, 2007

(30) Foreign Application Priority Data
Sep. 26, 2006 (KR) 10-2006-0093334

(51) Int. Cl. H01L 29/04; H01L 21/336

(52) U.S. Cl. 257/72; 438/160; 257/E29.003; 257/E21.414

(57) ABSTRACT

A thin film transistor substrate and a method of manufacturing the TFT substrate that are capable of simplifying manufacturing processes and protecting a gate driver from being eroded. The thin film transistor substrate includes an insulation substrate including a display area and a non-display area, a gate metal pattern including a first gate electrode formed on the insulation substrate in the display region, a gate insulation layer formed on the gate metal pattern, a first semiconductor pattern formed on the gate insulation layer overlapping the first gate electrode, a data metal pattern including a first source electrode and a first drain electrode that are connected to both ends of the first semiconductor pattern, a transparent conductive pattern connected to the first drain electrode and formed on the gate insulation layer, and a protective layer formed on the first semiconductor pattern and the data metal pattern.

### CROSS-REFERENCE TO RELATED APPLICATION

This application claims priority to Korean Patent Application No. 10-2006-93334, filed on Sep. 26, 2006, in the Korean Intellectual Property Office, the disclosure of which is herein incorporated by reference in its entirety.

### BACKGROUND OF THE INVENTION

1. Technical Field

The present disclosure relates to a liquid crystal display (“LCD”) device and, in particular, to a thin film transistor (“TFT”) substrate of an LCD device and a method of manufacturing the TFT substrate that are capable of simplifying the manufacturing process and preventing a gate driver from being eroded.

2. Discussion of Related Art

Generally, an LCD device includes a display panel having a plurality of gate lines and a plurality of data lines, a gate driver supplying a gate signal to the plurality of gate lines, and a data driver supplying a data signal to the plurality of data lines.

The gate driver and the data driver are mounted on a display panel in the form of a chip. Recently, a gate driver being built in the display panel has been developed to reduce the size of the display device and to improve productivity. The gate driver includes a first protective layer to cover a TFT mounted on the gate driver. A transparent electrode is formed along the first protective layer. In this case, the transparent electrode is formed on the top of the gate driver so as to be electrically connected to the display device. Because the transparent electrode is exposed to the outside of the display device, however, the gate driver may be eroded when the display device is driven for a long time at a high temperature and in high humidity.

A pixel electrode is electrically connected to a drain electrode through a contact hole formed in the first protective layer. The pixel electrode and the first protective layer are formed by a plurality of mask processes. A mask process of forming the pixel electrode and the first protective layer may include a series of processes, such as a thin film deposition process, a cleaning process, a photolithography process, an etching process, a photoresist stripping process, and an inspection process. Since such mask processes are necessary, the display device has a complicated manufacturing process, thereby leading to a significant increase in manufacturing cost. Also, because the pixel electrode is connected to the drain electrode through the contact hole, a contact area between the two electrodes becomes small and, thus, resistance is increased. Therefore, load power consumption may be increased.

### SUMMARY OF THE INVENTION

Exemplary embodiments of the present invention provide a TFT substrate and a method of manufacturing the same that is capable of simplifying a manufacturing process and preventing a gate driver from being eroded.

An exemplary embodiment of the present invention provides a thin film transistor substrate including an insulation substrate including a display area and a non-display area, a gate metal pattern including a first gate electrode formed on the insulation substrate in the display region, a gate insulation layer formed on the gate metal pattern, a first semiconductor pattern formed on the gate insulation layer overlapping the first gate electrode, a data metal pattern including a first source electrode and a first drain electrode that are connected to both ends of the first semiconductor pattern, a transparent conductive pattern connected to the first drain electrode and formed on the gate insulation layer, and a protective layer formed on the first semiconductor pattern and the data metal pattern.

The thin film transistor substrate further includes a second semiconductor pattern, wherein the gate metal pattern includes a second gate electrode and a gate signal line that are formed on the insulation layer corresponding to the non-display area, wherein the second semiconductor pattern is formed on the gate insulation layer overlapping the second gate electrode, and wherein the data metal pattern includes a second source electrode and a second drain electrode that are connected to both sides of the second semiconductor pattern.

The gate insulation layer includes a first contact hole exposing the gate signal line and that is formed on the second semiconductor pattern, and wherein the second source electrode is connected to the gate signal line through the first contact hole.

The gate metal pattern includes a gate pad portion connected to the gate signal line in the non-display area.

The gate insulation layer comprises a second contact hole exposing the gate pad portion.

The transparent conductive pattern is connected to the gate pad portion through the second contact hole and includes a first transparent electrode formed on the gate insulation layer.

The data metal pattern is formed in the non-display area and includes a data pad portion connected to the first source electrode.

The transparent conductive pattern is connected to the data pad portion and includes a second transparent electrode formed on the gate insulation layer.

An exemplary embodiment of the present invention provides a method of manufacturing a thin film transistor substrate. The method of manufacturing the thin film transistor substrate includes forming a gate metal pattern including a first gate electrode formed on an insulation layer in a display area, forming a gate insulation layer on the gate metal pattern, forming a first semiconductor pattern on the gate insulation layer overlapping the first gate electrode, forming a data metal pattern including a first source electrode and a first drain electrode that are connected to both ends of the first semiconductor pattern, forming a transparent conductive pattern including a pixel electrode connected to the first drain electrode on the gate insulation layer, and forming a protective layer on the first semiconductor pattern and the data metal pattern.

The step of forming the gate metal pattern comprises forming a second gate electrode and a gate signal line on the insulation substrate corresponding to the a non-display area, wherein the step of forming the semiconductor pattern comprises forming a second semiconductor pattern on the gate insulation layer overlapping the second gate electrode, and wherein the step of forming the data metal pattern comprises forming a second source and a second drain electrode connected to both sides of the second semiconductor pattern.

The step of forming the semiconductor pattern comprises forming a first contact hole exposing the gate signal line.

The step of forming the data metal pattern comprises connecting the gate signal line to the second source electrode through the first contact hole.

The step of forming the semiconductor pattern comprises forming a second contact hole exposing the gate pad portion.

The step of forming the transparent conductive pattern comprises forming on the gate insulation layer a first transparent conductive electrode connected to the gate pad portion through the second contact hole.

The step of forming the data metal pattern comprises forming a data pad portion connected to the first source electrode.

The step of forming the transparent conductive pattern comprises forming on the gate insulation layer a second transparent electrode connected to the data pad portion.

An exemplary embodiment of the present invention provides a method of manufacturing a thin film transistor substrate. The method of manufacturing the thin film transistor substrate includes a first mask process of forming a gate metal pattern including a first gate electrode on an insulation substrate corresponding to a display area, a second mask process of forming a gate insulation layer on the gate metal pattern and forming a first semiconductor pattern on the gate insulation layer overlapping the first gate electrode, a third mask process of forming a data metal pattern including a first source electrode and a first drain electrode connected to both sides of the first semiconductor pattern, and a fourth mask process of forming on the gate insulation layer a transparent conductive pattern including a pixel electrode connected to the first drain electrode and forming a protective layer on the first semiconductor pattern and the data metal pattern.

The first mask process includes forming a second gate electrode and a gate signal line on the insulation substrate corresponding to a non-display are, wherein the second mask process includes forming a second semiconductor pattern on the gate insulation layer overlapping the second gate electrode, and wherein the third mask process includes forming a second source and a second drain electrode connected to both sides of the second semiconductor pattern.

The fourth mask process includes depositing a transparent conductive layer on the insulation layer on which the data metal pattern is formed, depositing photoresist on the transparent conductive layer, exposing the photoresist corresponding to an area except for the transparent conductive pattern through a mask, removing the transparent conductive layer corresponding to an area except for the transparent conductive pattern by developing and etching the exposed photoresist, depositing the protective layer on the insulation substrate, and removing the photoresist and the protective layer formed on the transparent conductive pattern by a liftoff process.

Exemplary embodiments of the present invention are described in greater detail below with reference to the accompanying drawings. The same reference numbers will be used throughout the drawings to refer to the same or like parts. Detailed descriptions of well-known functions and structures incorporated herein are omitted to avoid obscuring the subject matter of the present invention.

While the present invention is susceptible of embodiment in many different forms, the exemplary embodiments are shown in drawings with the understanding that the present disclosure is to be considered as an exemplification of the principles of the invention and is not intended to limit the invention to the specific embodiments illustrated.

### BRIEF DESCRIPTION OF THE DRAWINGS

Exemplary embodiments of the present invention will be understood in more detail from the following descriptions taken in conjunction with the accompanying drawings, in which:

FIG. 1 is a block diagram of an LCD device according to an exemplary embodiment of the present invention;

FIG. 2 is a plan view of the LCD device according to an exemplary embodiment of the present invention;

FIG. 3 is a cross-sectional view of the LCD device taken along section lines I-I′, II-II′, III-III′, and IV-IV′ in FIG. 2;

FIGS. 4A to 4D are cross-sectional views illustrating a method of manufacturing a TFT substrate of the LCD device according to an exemplary embodiment of the present invention; and

FIGS. 5A to 5E are cross-sectional views illustrating a fourth masking process in the method of manufacturing the TFT substrate shown in FIG. 4D according to an exemplary embodiment of the present invention.

### DETAILED DESCRIPTION OF EXEMPLARY EMBODIMENTS

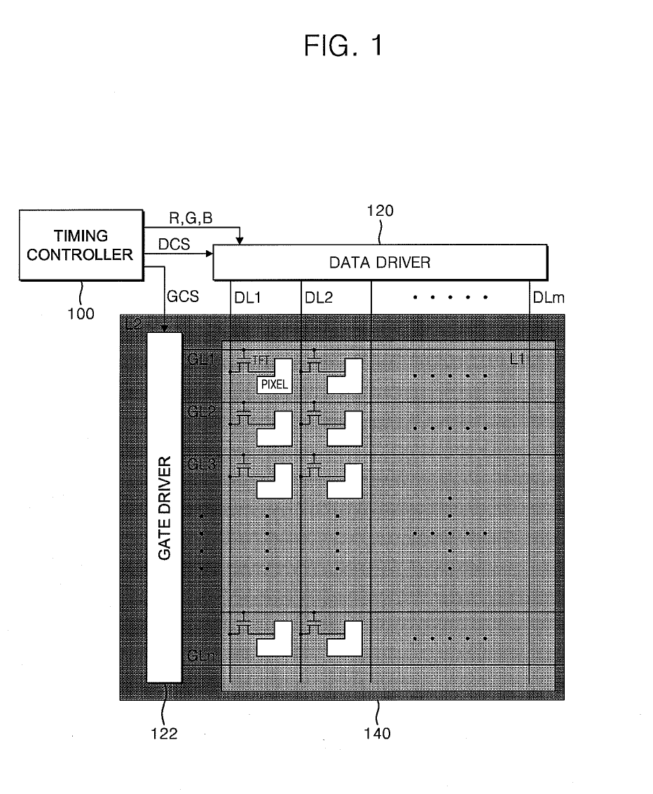

FIG. 1 is a block diagram of an LCD device according to an exemplary embodiment of the present invention.

The LCD device of the present invention includes a display panel 140, a data driver 120, a gate driver 122, and a timing controller 100.

The display panel 140 includes a TFT substrate, a color filter substrate (not shown), and a liquid crystal layer (not shown) sealed between the TFT substrate and the color filter. The color filter substrate includes red (R), green (G) and blue (B) color filters to display colors and a common electrode to apply a common voltage to the liquid crystal. The color filter substrate may also include a white color filter to improve the luminescence of the display device.

The TFT substrate includes a display area L1 and a non-display area L2. A plurality of gate lines GL1 to GLn, a plurality of data lines DL1 to DLm, TFTs, and pixel electrodes PIXEL are formed in the display area L1 of the TFT substrate. The plurality of gate lines GL1 to GLn and the plurality of data lines DL1 to DLm are arranged perpendicularly relative to each other. The TFTs are connected to the pixel electrode PIXEL in respective pixel regions.

For instance, the first TFT is connected to the first gate line GL1, the first data line DL1, and the pixel electrode.

The gate driver 122, a gate pad (not shown), and a data pad (not shown) are formed in the non-display area L2. The gate driver 122 is connected to the plurality of gate lines GL1 to GLn. The gate pad and the data pad are connected to the gate driver 122 and the plurality of data lines DL1-DLm, respectively.

The liquid crystal material has an anisotropic characteristic such that liquid crystal molecules change their orientation according to a difference of voltages applied to a common electrode and a pixel electrode. The liquid crystal molecules are twisted by the voltage difference so that it is possible to adjust the light transmissivity by controlling the voltages applied to the common electrode and the pixel electrode.

The data driver 120 generates a data signal corresponding to one line per horizontal period in response to a data control signal DCS received from the timing controller 100 and supplies the data signal to the plurality of data lines DL1 to DLm. The data driver 120 may be connected to the display panel 140 through a tape carrier package (not shown).

The timing controller 100 provides the pixel data signals R, G and B to the data driver 120. The timing controller 100 generates the data control signal DCS and a gate control signal GCS to control the data driver 120 and the gate driver 122, respectively, in response to external control signals. In this exemplary embodiment, the gate control signal GCS includes first and second clock signals, a scan trigger signal, and the like. The data control signal DCS includes a source start pulse signal, a source shift clock signal, a polarity control signal, and the like.

The gate driver 122 generates a gate driving signal per horizontal period in response to the gate control signal GCS received from the timing controller 100 and sequentially supplies the gate driving signal to the plurality of gate lines GL1 to GLn. The gate driver 122 includes a plurality of TFTs which are integrated on the non-display area L2 by using polysilicon or amorphous silicon having a high carrier. The TFTs of the gate driver 122 are simultaneously formed with the TFTs formed on the display area L1 of the display panel 140 by an identical process.

The gate driver 122 may include seven TFTs (not shown), for example, and a plurality of stages (not shown) connected to each other. The gate driver 122 supplies a scan signal, which is generated by the seven TFTs, to the first gate line GL1 during a first horizontal period. The gate driver 122 supplies the scan signal to the second gate line GL2 during a second horizontal period and supplies the scan signal to the third gate line GL3 during a third horizontal period. In this manner, the gate driver 122 sequentially generates one scan pulse per horizontal period to sequentially drive the plurality of gate lines GL1 to GLn.

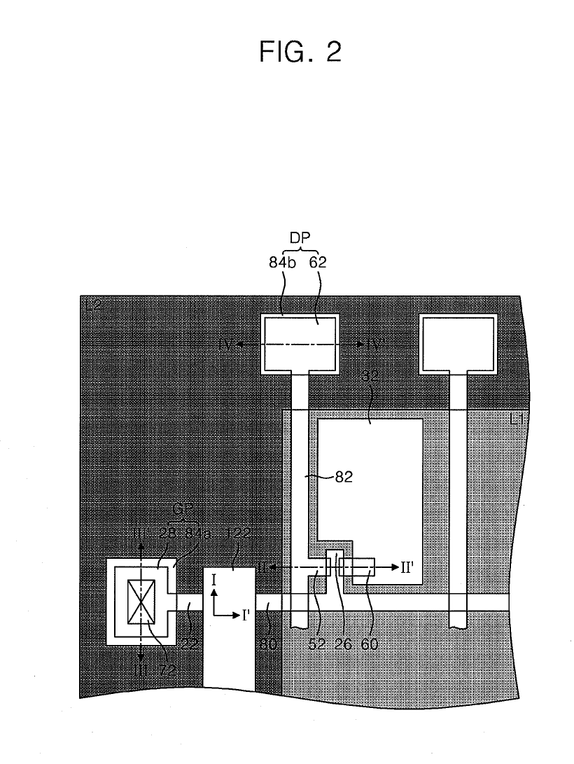

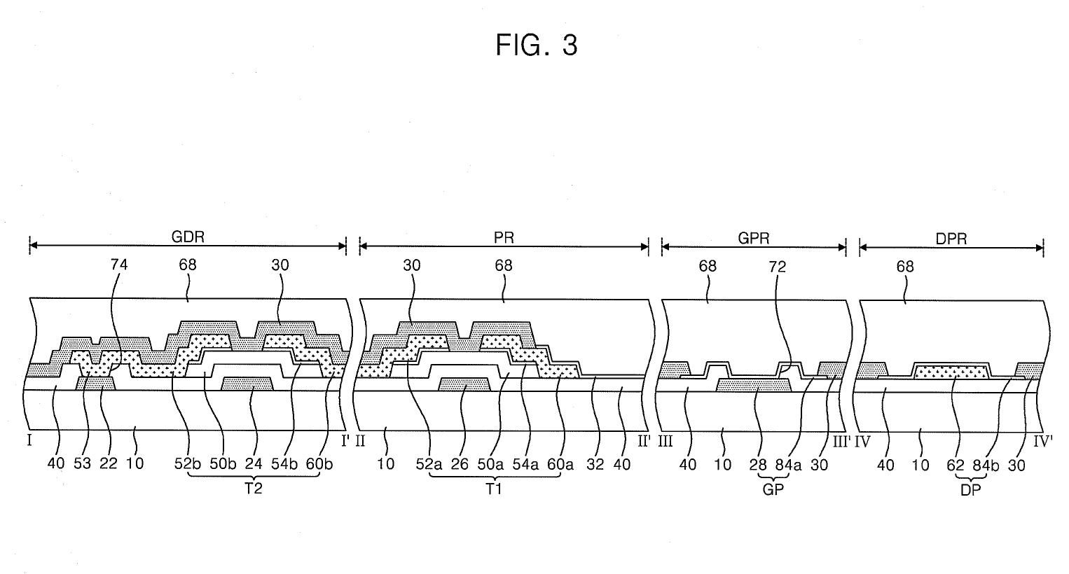

FIG. 2 is a plan view of the LCD device according to an exemplary embodiment of the present invention, and FIG. 3 is a cross-sectional view of the LCD device taken along section lines I-I′, II-II′, III-III′, and IV-IV′ in FIG. 2. The section lines I-I′, II-II′, III-III′, and IV-IV′ relate to a gate driver region GDR, a pixel region PR, a gate pad region GPR, and a data pad region DPR, respectively. The gate driver region GDR, the gate pad region GPR, and the data pad region DPR are formed in the non-display area L2 of the TFT substrate, and the pixel region PR is formed in the display area L1 of the TFT substrate.

Referring to FIGS. 2 and 3, a second TFT T2 and a gate signal line 22 are formed in the gate driver region GDR on an insulation substrate 10. The second TFT T2 includes a second gate electrode 24, a second active layer 50b, a second ohmic contact layer 54b, a second source electrode 52b, and a second drain electrode 60b.

The second active layer 50b overlaps the second gate electrode 24 with a gate insulation layer 40 disposed therebetween to form a channel. The second ohmic contact layer 54b is formed between the second active layer 50b and the second source and drain electrodes 52b and 60b. The second drain electrode 60b is connected to other TFTs (not shown) included in the gate driver 122. The second source electrode 52b is connected to the gate signal line 22 by a connection signal line 53 exposed through a first contact hole 74. The gate signal line 22 is preferably made of the same metal material as the second gate electrode 24.

A first protective layer 30 is formed on the connection signal line 53, the second source and drain electrodes 52b and 60b, and the second active layer 50b. A second protective layer 68 is formed on the first protective layer 30. In this exemplary embodiment, it is desirable that the first protective layer 30 be an inorganic layer and the second protective layer 68 be an organic layer. The first and second protective layers 30 and 68 prevent the second TFT T2 and the gate signal line 22 from being eroded.

The gate signal line 22 supplies the gate driving signal to the second TFT T2 through the connection signal line 53 and the second TFT T2 supplies the gate driving signal to the other TFTs (not shown) through the second drain electrode 60b.

A first TFT T1 and a pixel electrode 32 are formed in the pixel region PR formed on the insulation substrate 10.

The first TFT T1 includes a first gate electrode 26, a first active layer 50a, a first ohmic contact layer 54a, a first source electrode 52a, and a first drain electrode 60a. The first gate electrode 26 is connected to a gate line 80, shown in FIG. 2, and receives the gate driving signal through the gate line 80. The first source electrode 52a is connected to a data line 82, shown in FIG. 2, and receives the data signal through the data line 82. The first drain electrode 60a is connected to the pixel electrode 32. The first active layer 50a overlaps the first gate electrode 26 with the gate insulation layer 40 disposed therebetween to form a channel. The first ohmic contact layer 54a is formed between the first active layer 50a and the first source and drain electrodes 52a and 60a.

The pixel electrode 32 is directly connected to the first drain electrode 60a and supplies the data signal generated from the first drain electrode 60a to the liquid crystal. The first protective layer 30 is formed on the first source and drain electrodes 52a and 60a and the first active layer 50a. The second protective layer 68 is formed on the first protective layer 30 and the pixel electrode 32.

The pixel electrode 32 according to an exemplary embodiment of the present invention is directly connected to the first drain electrode 60a, as opposed to a conventional pixel electrode connected to a drain electrode through a contact hole. Therefore, a contact area between the pixel electrode 32 and the first drain electrode 60a according to an exemplary embodiment of the present invention may be broader than a contact area between the pixel electrode and the drain electrode as known in the prior art.

Because the contact area between the pixel electrode 32 and the first drain electrode 60a becomes broadened, a resistance of the pixel electrode 32 and the first drain electrode 60a is decreased, thereby reducing the load power. Further, since the pixel electrode 32 is simultaneously formed with the first protective layer 30, a mask manufacturing process may be reduced.

Next, a gate pad GP is formed in the gate pad region GPR on the insulation substrate 10. The gate pad GP supplies the gate control signal generated from the timing controller 100 to the gate driver 122 through the gate signal line 22. In this exemplary embodiment, the gate pad GP is connected to the gate driver 122 through the gate signal line 22.

The gate pad GP includes a first transparent electrode 84a electrically connected to the timing controller 100 and a gate pad portion 28 connected to the gate signal line 22. The first transparent electrode 84a is connected to the gate pad portion 28 through a second contact hole 72 formed on the gate insulation layer 40.

Referring to the data pad region DPR, a data pad DP is formed on the gate insulation layer 40 in the data pad region DPR. The data pad DP supplies the data signal generated from timing controller 100, shown in FIG. 2, to the first TFT T1 of the pixel region PR through a data line 82, shown in FIG. 2.

The data pad DP includes a second transparent electrode 84b electrically connected to the timing controller 100 and a data pad portion 62 connected to the data line 82. The second transparent electrode 84b is formed on the data pad portion 62 formed on the insulation layer 40 and is connected to the data pad portion 62.

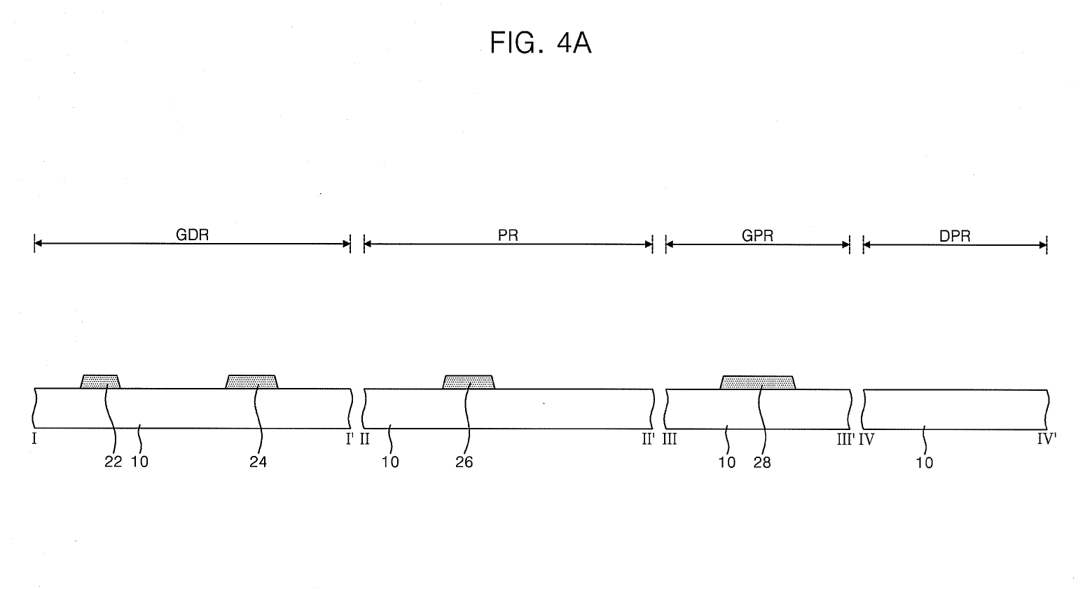

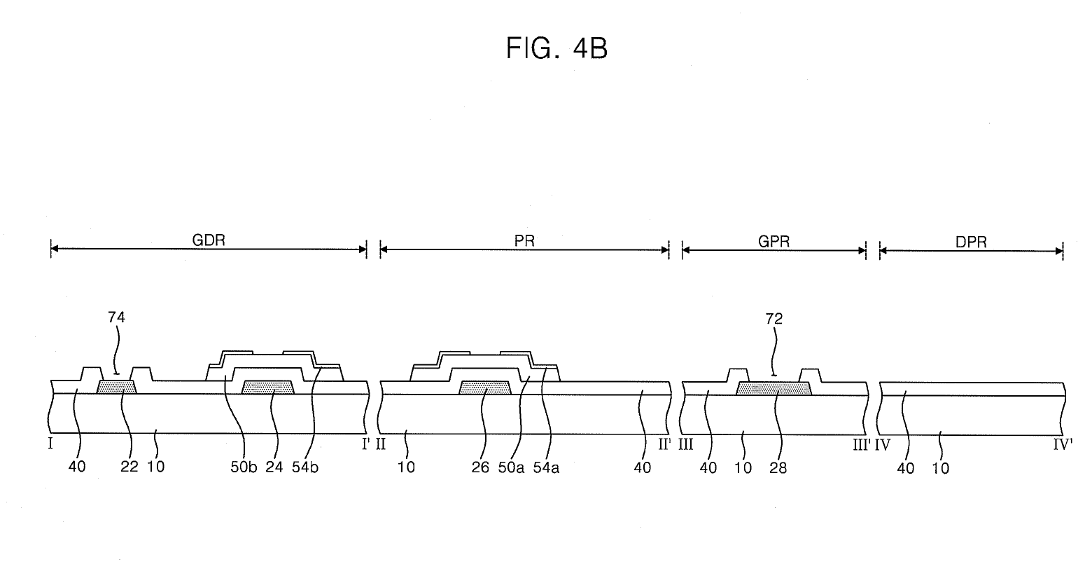

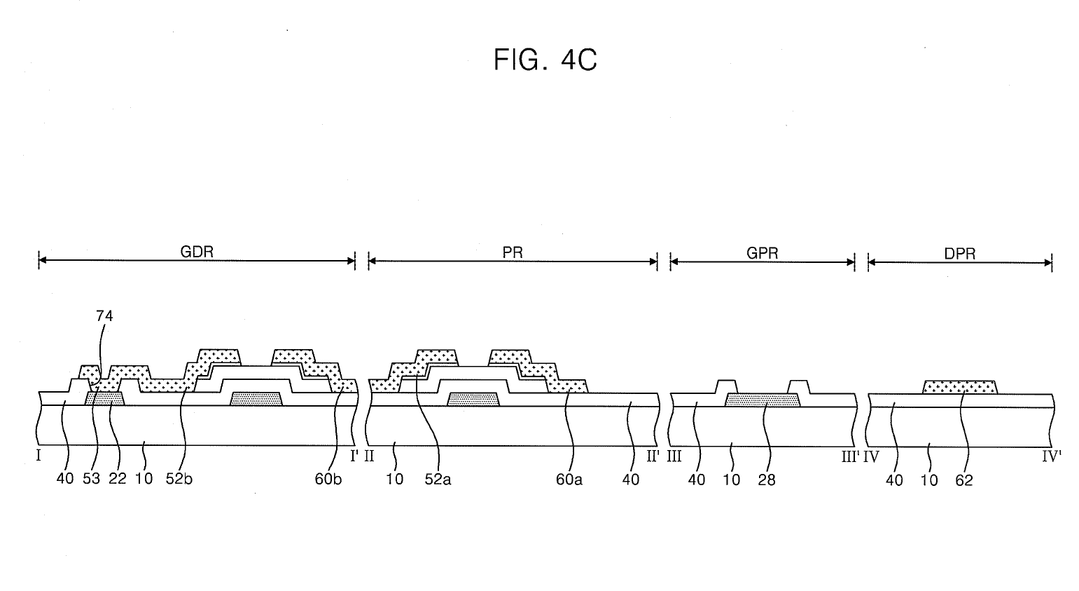

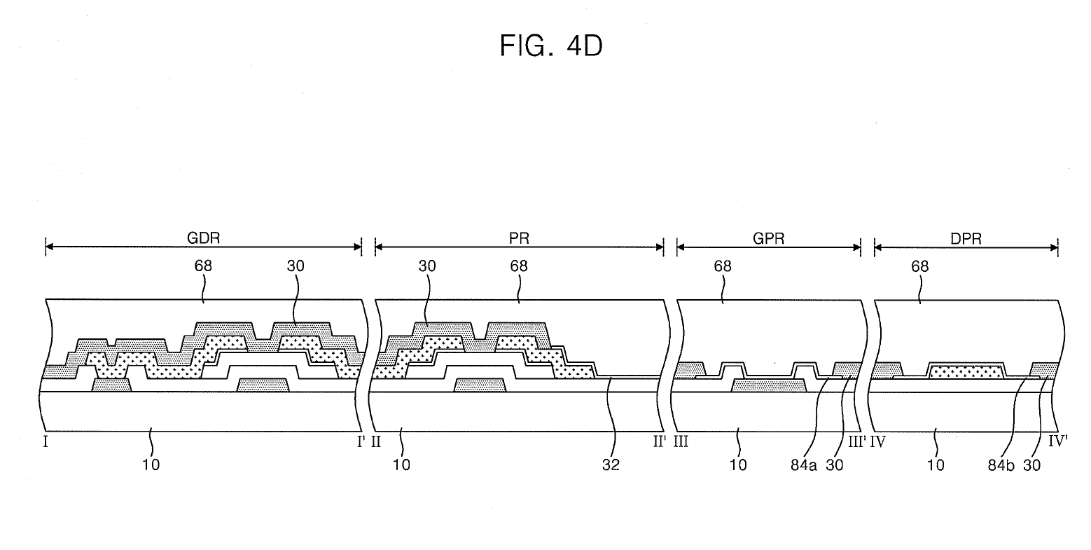

FIGS. 4A to 4D are cross-sectional views illustrating a method of manufacturing a TFT substrate of the LCD device according to an exemplary embodiment of the present invention. Section lines I-I′, II-II′, III-III′, and IV-IV′ shown in FIGS. 4A to 4D relate to the gate driver region GDR, the pixel region PR, the gate pad region GPR, and the data pad region DPR, respectively.

FIG. 4A is a cross-sectional view illustrating a first mask process of the method of manufacturing the TFT substrate according to an exemplary embodiment of the present invention. A gate pattern is formed on a prescribed area of the insulation substrate 10. The gate pattern includes the gate signal line 22 and the second gate electrode 24 formed in the gate driver region GDR, the first gate electrode 26 formed in the pixel region PR, and the gate pad portion 28 formed in the gate pad region GPR.

More specifically, a gate metal layer is formed on the insulation substrate 10 by a deposition method, such as sputtering. The gate metal layer is patterned by a photolithography process using the first mask and an etching process, thereby forming the gate signal line 22 and the second gate electrode 24 of the gate driver region GDR, the first gate electrode 26 of the pixel region PR, and the gate pad portion 28 of the gate pad region GPR. The gate metal layer may be formed of a metal material such as Mo, Ti, Cu, A1Nd, Al, Cr, Mo alloy, Cu alloy, or Al alloy in a single or multi-layer structure of such materials.

FIG. 4B is a cross-sectional view illustrating a second mask process of the method of manufacturing the TFT substrate according to an exemplary embodiment of the present invention. The gate insulation layer 40 is formed on the insulation substrate 10 on which a gate pattern is formed. A semiconductor pattern is formed including the first and second ohmic contact layers 54a and 54b and the first and second active layers 50a and 50b. The second ohmic contact layer 54b and the second active layer 50b are formed on the second gate electrode 24 in the gate driver region GDR and the first ohmic contact layer 54a and the first active layer 50a are formed on the first gate electrode 26 in the pixel region PR.

More specifically, an insulation material, an amorphous silicon layer, and an n+ or p+ impurity doped amorphous silicon layer are sequentially deposited on the insulation substrate 10 on which the gate pattern is formed by using a plasma enhanced chemical vapor deposition (“PECVD”) method. In this exemplary embodiment, the insulation material constitutes the gate insulation layer 40 and may include an inorganic insulation material such as silicon oxide (SiOx) or silicon nitride (SiNx), or an organic insulation material.

Next, the impurity doped amorphous silicon layer, the amorphous silicon layer, and the insulation material are patterned by a photolithography process using the second mask and an etching process. The first and second contact holes 74 and 72 are formed in the gate insulation layer 40, thereby forming the semiconductor pattern on the second and first gate electrodes 24 and 26.

The first and second contact holes 74 and 72 are formed in the gate driver region GDR and the gate pad region GPR to expose the gate signal line 22 and the gate pad portion 28, respectively. The semiconductor pattern includes semiconductor layers 50b and 54b on the second gate electrode 24 in the gate driver region GDR and semiconductor layers 50a and 54a on the first gate electrode 26 in the pixel region PR.

FIG. 4C is a cross-sectional view illustrating a third mask process of the method of manufacturing the TFT substrate according to an exemplary embodiment of the present invention. A source/drain metal pattern is formed on the insulation substrate 10 on which the semiconductor pattern and the gate insulation layer 40 are formed. In this exemplary embodiment, the source/drain metal pattern includes the second source and drain electrodes 52b and 60b of the gate driver region GDR, the first source and drain electrodes 52a and 60a of the pixel region PR, and the data pad portion 62 of the data pad region DPR.

More specifically, a source/drain metal layer is formed on the insulation substrate 10 on which the semiconductor pattern and the gate insulation layer 40 are formed by a deposition method, such as sputtering. The source/drain metal layer is patterned by a photolithography process using the third mask and an etching process, thereby forming the second source and drain electrodes 52b and 60b, the first source and drain electrodes 52a and 60a, and the data pad portion 62. At this time, the connection signal line 53, which is connected to the gate signal line 22 through the first contact hole 74 and extended to the second source electrode 52b, is formed in the gate driver region GDR. The source/drain metal layer may be formed of a metal material such as Mo, Ti, Cu, A1Nd, Al, Cr, Mo alloy, Cu alloy, or Al alloy in a single or multi-layer structure formed of such materials.

FIG. 4D is a cross-sectional view illustrating a fourth mask process of the method of manufacturing the TFT substrate according to an exemplary embodiment of the present invention. A transparent conductive pattern is formed on the insulation substrate 10 on which the source/drain metal pattern is formed. The transparent conductive pattern includes the pixel electrode 32 of the pixel region PR, the first transparent electrode 84a of the gate pad region GPR, and the second transparent electrode 84b of the data pad region DPR.

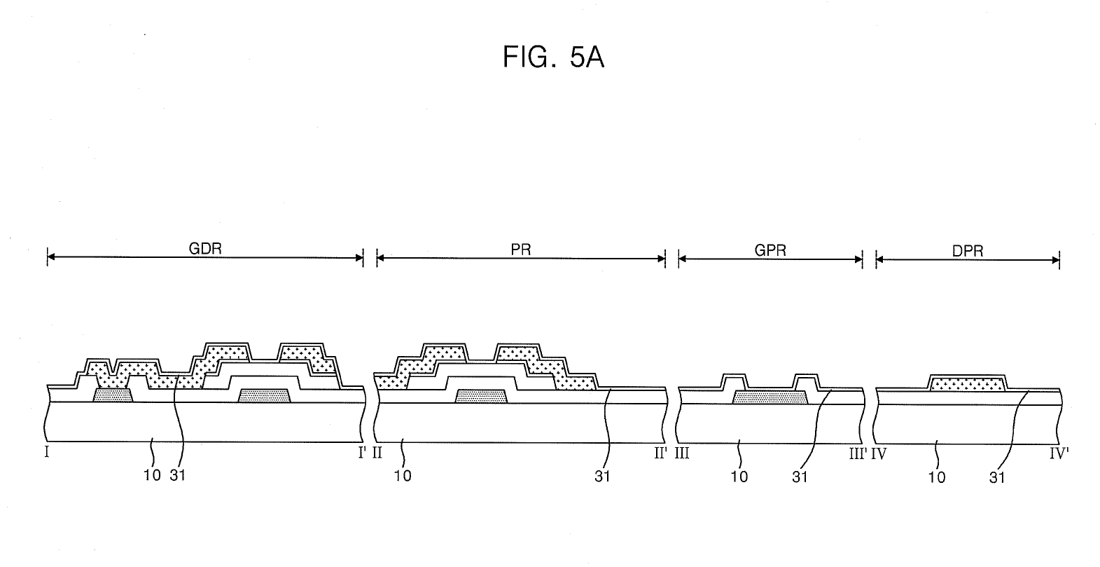

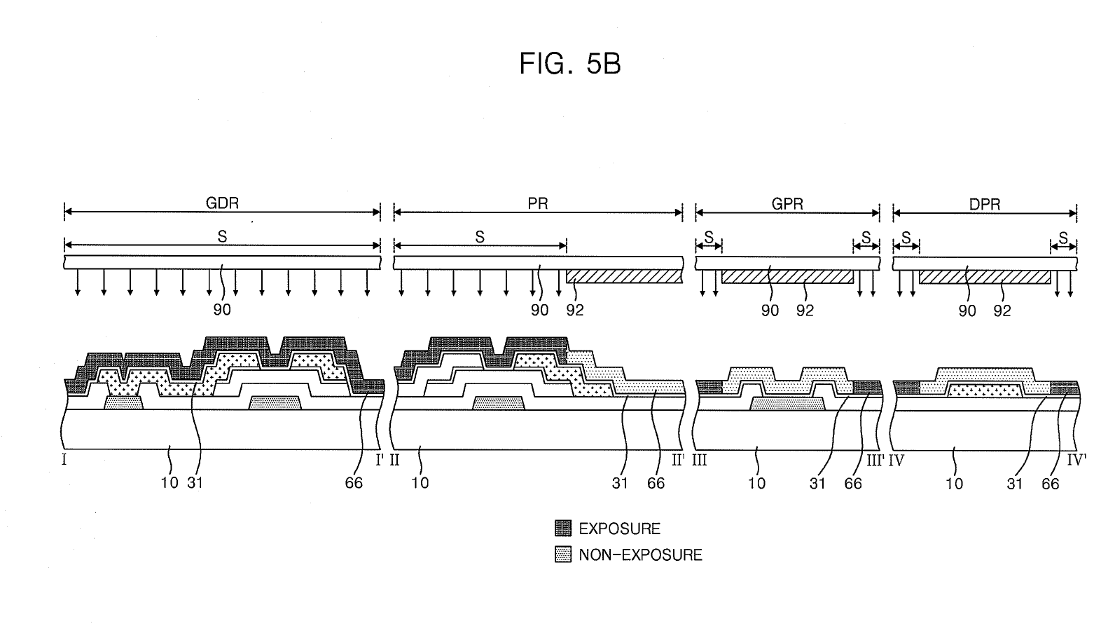

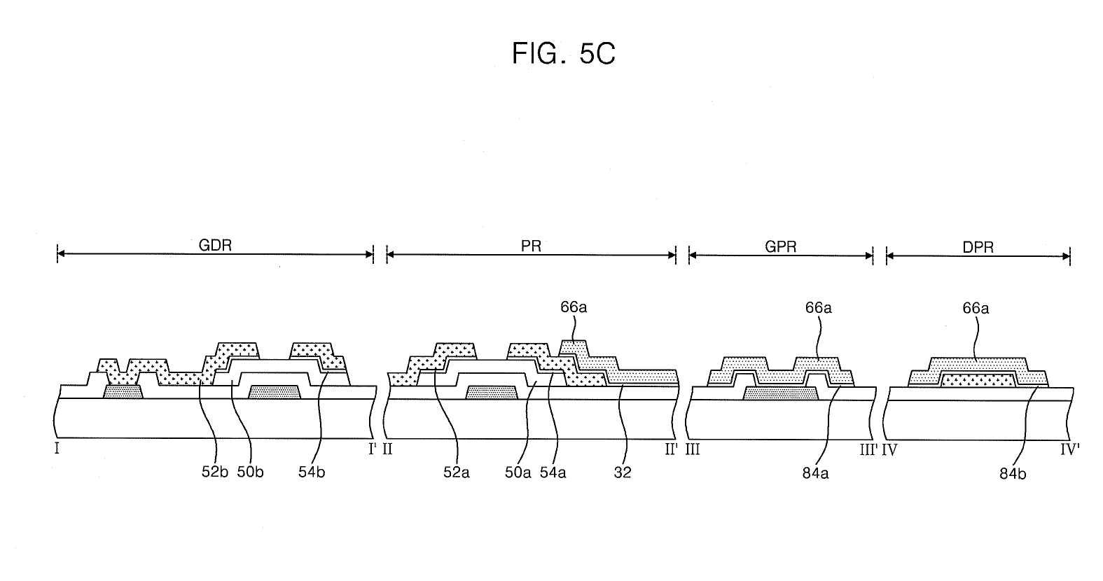

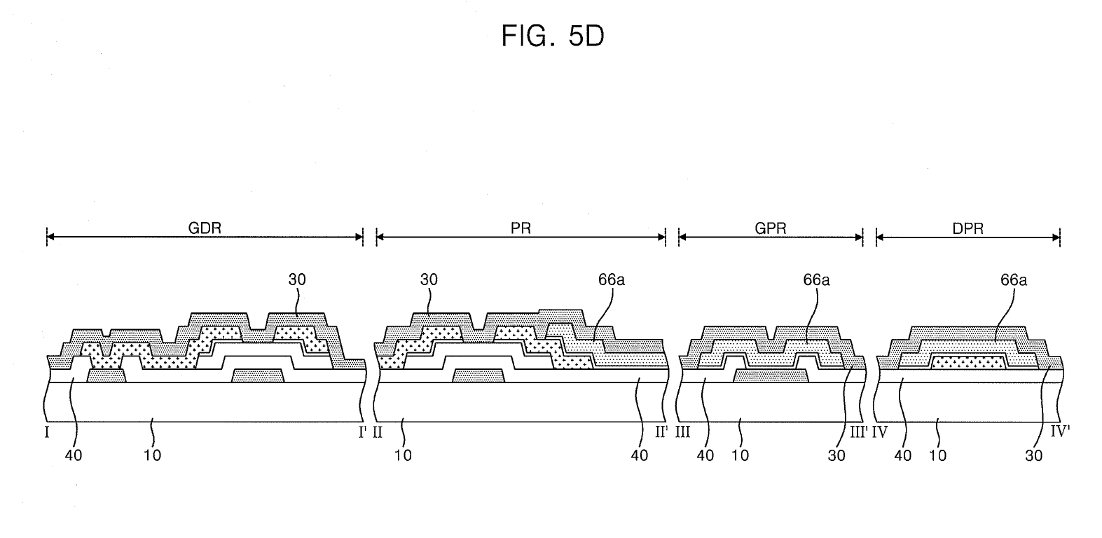

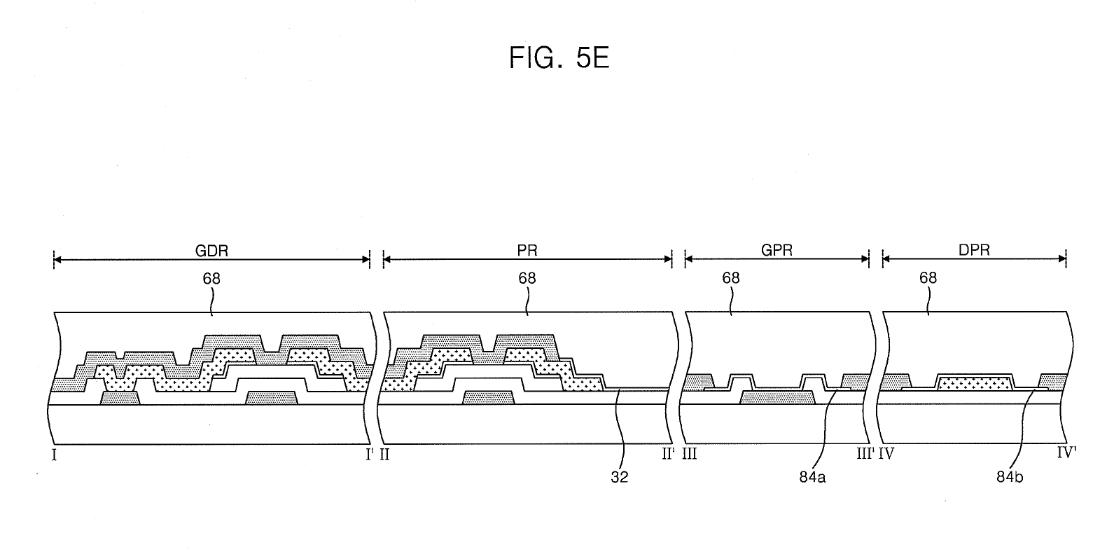

The fourth mask process of the method of manufacturing the TFT substrate according to an exemplary embodiment of the present invention will be described in detail with reference to FIGS. 5A to 5D. Referring to FIGS. 5A to 5D, section lines I-I′, II-II′, III-III′, and IV-IV′ show the gate driver region GDR, the pixel region PR, the gate pad region GPR, and the data pad region DPR, respectively.

As illustrated in FIG. 5A, a transparent conductive layer 31 is formed on the whole surface of the insulation substrate 10 on which the source/drain metal pattern is formed using a deposition method, such as sputtering. The transparent conductive layer 31 is preferably made of an indium tin oxide (ITO), a tin oxide (TO), an indium zinc oxide (IZO) or an amorphous-indium tin oxide (a-ITO).

Referring to FIG. 5B, photoresist 66 is deposited to cover the transparent conductive layer 31. A photolithography process is performed by a mask process using a mask substrate 90 including a light-blocking layer 92. An area S of the mask substrate 90, except for an area of the light-blocking layer 92, corresponds to an exposure area on the transparent conductive layer 31 formed on the insulation substrate 10. In this exemplary embodiment, the area on which the light-blocking layer 92 is formed includes the regions corresponding to the pixel electrode 32, shown in FIG. 5C, of the pixel region PR, a first transparent electrode 84a, shown in FIG. 5C, of the gate pad region GPD, and the second transparent electrode 84b, shown in FIG. 5C, of the data pad region DPR.

Referring to FIG. 5C, the transparent conductive layer 31 of the exposure area is removed by an etching process, thereby exposing the second active layer 50b, and the second source and drain electrodes 52b and 54b of the gate driver region GDR, and the first active layer 50a, and the first source and drain electrodes 52a and 54a of the pixel region PR. A photoresist pattern 66a remains on the area except for the exposure area, that is, on the pixel electrode 32 of the pixel region PR, the first transparent electrode 84a of the gate pad region GPR, and the second transparent electrode 84b of the data pad region DPR.

Referring to FIG. 5D, an inorganic insulation material is deposited on the whole surface of the insulation substrate 10 on which the photoresist pattern 66a is formed by using a PECVD, spin coating, or spinless coating method to form the first protective layer 30. In this exemplary embodiment, it is desirable that the inorganic insulation layer constituting the first protective layer 30 be formed of the same material as the gate insulation layer 40.

Next, as shown in FIG. 5E, the photoresist pattern 66a and the inorganic insulation material formed on the photoresist pattern 66a, shown in FIG. 5D, are simultaneously removed by a liftoff process using a stripper, thereby exposing the pixel electrode 32 of the pixel region PR, the first transparent electrode 84a of the gate pad region GPR, and the second transparent electrode 84b of the data pad region DPR.

Finally, an organic insulation material is deposited on the whole surface of the insulation substrate 10 on which the pixel electrode 32, the first transparent electrode 84a, and the second transparent electrode 84b are exposed, thereby forming the second protective layer 68. The organic insulation material constituting the second protective layer 68 may be made of an epoxy-based acrylic resin.

According to an exemplary embodiment of the present invention, since the TFT substrate is manufactured by altering the manufacturing order of the protective layer and the pixel electrode and by using a liftoff process, the number of mask processes is reduced. Therefore, the manufacturing cost is reduced. Moreover, since the pixel electrode is directly connected to the drain electrode, power consumption is reduced. In addition, since the protective layer covers the pixel electrode, the gate driver is prevented from being eroded.

While the invention has been shown and described with reference to exemplary embodiments thereof, it will be understood by those skilled in the art that various changes in form and details may be made therein without departing from the spirit and scope of the invention as defined by the appended claims.

What is claimed is:

1. A thin film transistor substrate comprising:
an insulation substrate including a display area and a non-display area;
a gate metal pattern including a first gate electrode formed on the insulation substrate in the display area;
a gate insulation layer formed on the gate metal pattern;
a first semiconductor pattern formed on the gate insulation layer overlapping the first gate electrode;
a data metal pattern including a first source electrode and a first drain electrode that are connected to both ends of the first semiconductor pattern;
a transparent conductive pattern connected to the first drain electrode and formed on the gate insulation layer; and
a protective layer formed on the first semiconductor pattern and the data metal pattern.

2. The thin film transistor substrate of claim 1, further comprising a second semiconductor pattern,
wherein the gate metal pattern includes a second gate electrode and a gate signal line that are formed on the insulation layer corresponding to the non-display area,
wherein the second semiconductor pattern is formed on the gate insulation layer overlapping the second gate electrode, and
wherein the data metal pattern includes a second source electrode and a second drain electrode that are connected to both sides of the second semiconductor pattern.

3. The thin film transistor substrate of claim 2, wherein the gate insulation layer includes a first contact hole exposing the gate signal line and formed on the second semiconductor pattern, and wherein the second source electrode is connected to the gate signal line through the first contact hole.

4. The thin film transistor substrate of claim 3, wherein the gate metal pattern includes a gate pad portion connected to the gate signal line in the non-display area.

5. The thin film transistor substrate of claim 4, wherein the gate insulation layer comprises a second contact hole exposing the gate pad portion.

6. The thin film transistor substrate of claim 5, wherein the transparent conductive pattern is connected to the gate pad portion through the second contact hole and includes a first transparent electrode formed on the gate insulation layer.

7. The thin film transistor substrate of claim 3, wherein the data metal pattern is formed in the non-display area and includes a data pad portion connected to the first source electrode.

8. The thin film transistor substrate of claim 7, wherein the transparent conductive pattern is connected to the data pad portion and includes a second transparent electrode formed on the gate insulation layer.

9. A method of manufacturing a thin film transistor substrate, the method comprising:
forming a gate metal pattern including a first gate electrode formed on an insulation layer in a display area;
forming a gate insulation layer on the gate metal pattern;
forming a first semiconductor pattern on the gate insulation layer overlapping the first gate electrode;
forming a data metal pattern including a first source electrode and a first drain electrode that are connected to both ends of the first semiconductor pattern;
forming a transparent conductive pattern including a pixel electrode connected to the first drain electrode on the gate insulation layer; and
forming a protective layer on the first semiconductor pattern and the data metal pattern.

10. The method of claim 9, wherein the step of forming the gate metal pattern comprises forming a second gate electrode and a gate signal line on the insulation substrate corresponding to a non-display area, wherein the step of forming the semiconductor pattern comprises forming a second semiconductor pattern on the gate insulation layer overlapping the second gate electrode, and wherein the step of forming the data metal pattern comprises forming a second source and a second drain electrode connected to both sides of the second semiconductor pattern.

11. The method of claim 10, wherein the step of forming the semiconductor pattern comprises forming a first contact hole exposing the gate signal line.

12. The method of claim 11, wherein the step of forming the data metal pattern comprises connecting the gate signal line to the second source electrode through the first contact hole.

13. The method of claim 12, wherein the step of forming the semiconductor pattern comprises forming a second contact hole exposing the gate pad portion.

14. The method of claim 13, wherein the step of forming the transparent conductive pattern comprises forming on the gate insulation layer a first transparent conductive electrode connected to the gate pad portion through the second contact hole.

15. The method of claim 14, wherein the step of forming the data metal pattern comprises forming a data pad portion connected to the first source electrode.

16. The method of claim 15, wherein the step of forming the transparent conductive pattern comprises forming on the gate insulation layer a second transparent electrode connected to the data pad portion.

17. A method of manufacturing a thin film transistor substrate, the method comprising:
a first mask process of forming a gate metal pattern including a first gate electrode on an insulation substrate corresponding to a display area;
a second mask process of forming a gate insulation layer on the gate metal pattern and forming a first semiconductor pattern on the gate insulation layer overlapping the first gate electrode;
a third mask process of forming a data metal pattern including a first source electrode and a first drain electrode connected to both sides of the first semiconductor pattern; and
a fourth mask process of forming on the gate insulation layer a transparent conductive pattern including a pixel electrode connected to the first drain electrode and forming a protective layer on the first semiconductor pattern and the data metal pattern.

18. The method of claim 17, wherein the first mask process includes forming a second gate electrode and a gate signal line on the insulation substrate corresponding to a non-display are, wherein the second mask process includes forming a second semiconductor pattern on the gate insulation layer overlapping the second gate electrode, and wherein the third mask process includes forming a second source and a second drain electrode connected to both sides of the second semiconductor pattern.

19. The method of claim 18, wherein the fourth mask process includes:
depositing a transparent conductive layer on the insulation layer on which the data metal pattern is formed;
depositing photoresist on the transparent conductive layer;
exposing the photoresist corresponding an area, except for the transparent conductive pattern, through a mask;
removing the transparent conductive layer of an area, except for the transparent conductive pattern, by developing and etching the exposed photoresist;
depositing the protective layer on the insulation substrate; and
removing the photoresist and the protective layer formed on the transparent conductive pattern by a liftoff process.
